(19) United States
(12) Patent Application Publication
(10) Pub. No.: US 2026/0142464 A1
(43) Pub. Date: May 21, 2026

(54) Power-Cycling Device

(71) Applicant: Vitalchat, Inc., Ashburn, VA (US)

(72) Inventor: Ghafran Abbas, Ashburn, VA (US)

(21) Appl. No.: 18/949,603

(22) Filed: Nov. 15, 2024

(51) Int. Cl. H02J 3/14; G01R 19/165; H02J 13/00

(52) U.S. Cl. CPC H02J 3/14; G01R 19/16571; H02J 13/12; H02J 13/13

(57) ABSTRACT

An apparatus includes a relay configured to control a flow of electricity from a power supply to an electronic device, a relay controller configured to control an operation of the relay, and a sensor communicatively connected to the relay controller and configured to measure a power consumption of the electronic device. The relay controller is configured to detect a cessation of the power consumption of the electronic device based on signals from the sensor and cause the relay to power cycle the electronic device in response to detecting the cessation of the power consumption.

### FIELD

This disclosure relates generally to automatic power cycling based on the cessation of power consumption.

### SUMMARY

A first aspect is an apparatus for an automatic power-cycling device. The apparatus includes a relay configured to control a flow of electricity from a power supply to an electronic device; a relay controller configured to control an operation of the relay; a sensor communicatively connected to the relay controller and configured to measure a power consumption of the electronic device wherein the relay controller is configured to detect, based on signals from the sensor, a cessation of the power consumption of the electronic device; and cause the relay to power cycle the electronic device in response to detecting the cessation of the power consumption.

A second aspect is a method for an automatic power-cycling device. The method includes monitoring, based on sensor data, a power consumption of an electronic device receiving a flow of electricity from a power supply through a relay; detecting, based on the sensor data, a cessation of the power consumption; and causing, by a relay controller, the relay to power cycle the power of the electronic device in response to detecting the cessation of the power consumption.

A third aspect is a non-transitory computer-readable medium storing instructions operable to cause one or more processors to perform operations that include receiving, from a sensor, a power consumption of an electronic device receiving a flow of electricity from a power supply through a relay; determining a cessation of the power consumption based on the power consumption being less than a predetermined power consumption level; and cycling the power of the electronic device in response to detecting the cessation of the power consumption.

These and other aspects of the present disclosure are disclosed in the following detailed description of the embodiments, the appended claims, and the accompanying figures.

It will be appreciated that aspects can be implemented in any convenient form. For example, aspects may be implemented by appropriate computer programs which may be carried on appropriate carrier media which may be tangible carrier media (e.g., disks) or intangible carrier media (e.g., communications signals). Aspects may also be implemented using suitable apparatus which may take the form of programmable computers running computer programs arranged to implement the methods and/or techniques disclosed herein. Aspects can be combined such that features described in the context of one aspect may be implemented in another aspect.

### BRIEF DESCRIPTION OF THE DRAWINGS

The disclosure is best understood from the following detailed description when read in conjunction with the accompanying drawings.

FIG. 1 is a schematic of an example of a system according to implementations of this disclosure.

FIG. 2 is a block diagram of an example of a computing device.

FIG. 3 is a block diagram of an example of a system for power cycling electronic devices according to implementation of this disclosure.

FIG. 4 is a block diagram of a power-cycling device.

FIG. 5 is an example of a flowchart of a technique for power cycling an electronic device using a power-cycling device according to an implementation of this disclosure.

FIG. 6 is an example of a flowchart of a technique for power cycling an electronic device.

FIG. 7 is an example of a flowchart of a technique for determining the cessation of a power consumption of an electronic device.

FIG. 8 is an example of a flowchart of a technique for power cycling multiple electronic devices.

These and other aspects of the present disclosure are disclosed in the following detailed description of the embodiments, the appended claims, and the accompanying figures.

It will be appreciated that aspects can be implemented in any convenient form. For example, aspects may be implemented by appropriate computer programs which may be carried on appropriate carrier media which may be tangible carrier media (e.g., disks) or intangible carrier media (e.g., communications signals). Aspects may also be implemented using a suitable apparatus, which may take the form of programmable computers running computer programs arranged to implement the methods and/or techniques disclosed herein. Aspects can be combined such that features described in the context of one aspect may be implemented in another aspect.

### DETAILED DESCRIPTION

Managing devices in modern technological environments, such as commodity hardware like computers, cameras, and other peripherals, poses significant challenges. These devices, often used in settings that require hands-off (e.g., no or minimal human) management, sometimes malfunction in ways that necessitate a physical power cycle—essentially unplugging and then reconnecting them to the power supply. Therefore, it is essential that such devices can be power cycled, without in-person intervention to ensure optimal operation and successful diagnostics.

A primary challenge is determining when a power cycle is necessary and implementing the power cycle without requiring in-person intervention. While conventional reboot procedures offer some solutions, they may not fully address the need to completely cut off power in a way that physically unplugging a device does. A reboot, initiated through software commands, involves a controlled shutdown and a subsequent restart of the device. However, during a reboot the device does not stop receiving power from the power supply, as such, certain components retain residual power, preventing a full device reset. In contrast, power cycling involves a complete interruption of electrical power ensuring a true hardware reset. Additionally, the capability to remotely reboot may not be universally available for all devices, particularly for certain peripherals.

Presently, three solutions or approaches may be used to address the need to power cycle a device. The first is a manual power cycle, requiring physical disconnection and reconnection of the device to the power supply, which is time-consuming and operationally inefficient, at the least, especially when devices are in hard-to-reach or secured locations. The second is an automated, timed power cycle, which can lead to unnecessary downtime as it operates on a fixed schedule without regard to the device's actual need for a power cycle. The third is a remote reboot, which, while offering a degree of control from afar, may not always achieve the desired outcome. A remote reboot often leaves certain components, such as the power supply or network interface, partially powered, preventing a complete system reset. This residual power can harbor lingering issues within the hardware or firmware of the device, hindering a clean recovery. Additionally, externally powered peripherals connected to the device can remain active during a remote reboot, potentially contributing to ongoing malfunctions or conflicts. None of these solutions or approaches address the need for effectuating a power cycle at a device and all connected peripherals without in-person intervention.

Implementations according to this disclosure can automatically trigger, by a power-cycling device, a power cycle of one or more electronic devices upon detecting, by the power-cycling device, the cessation of a power consumption by at least one of the one or more electronic devices. In response to detecting the cessation of the power consumption, the power-cycling device automatically power cycles at least some of the one or more electronic devices. As such, no in-person intervention is required to power cycle devices to correct malfunctions. An electronic device that is power cycled by the power-cycling device is referred to herein as a connected device. The power-cycling device is said to power the connected device. That is, any power (e.g., electricity) that powers the connected device flows through and is controlled by the power-cycling device. The power-cycling device monitors the power consumption of the connected device. The power consumption of the connected device can be measured by measuring the current or the voltage drawn by the connected device. If the power consumption is detected to be below a minimum threshold value, the power-cycling device temporarily terminates the flow of electricity to the connected device therewith causing a connected device to power cycle (e.g., to reset).

The minimum threshold value represents the lowest expected value of the power consumption of the connected device during normal operation. The minimum threshold value can be calibrated (e.g., set, configured, or selected) to distinguish between normal power states and abnormal power states indicative of a malfunction or shutdown. For example, if the connected device is a computer, the minimum threshold value can be set slightly above the average power consumption of the computer during normal operation. Setting the minimum threshold value slightly above the average power consumption helps to ensure that the power-cycling device does not inadvertently trigger a power cycle during normal operations. The specific minimum threshold value can be determined empirically through testing or based on the technical specifications of the connected device. In some implementations, the threshold may be dynamically adjusted based on the historical power consumption of the connected device.

To illustrate, an in-room monitoring system with a connected camera may stop functioning properly due to a malfunction between the camera and the computing device. The computing device can be remotely shutdown in order to trigger a full power cycle of the computing device. As such the power-cycling device detects that the power consumption of the computing device is below the minimum threshold value. Once the power-cycling device detects that the power consumption is below the minimum threshold value, the power-cycling device may automatically perform a power cycle.

Details of a power-cycling device are described herein with initial reference to a system in which the teachings herein can be implemented.

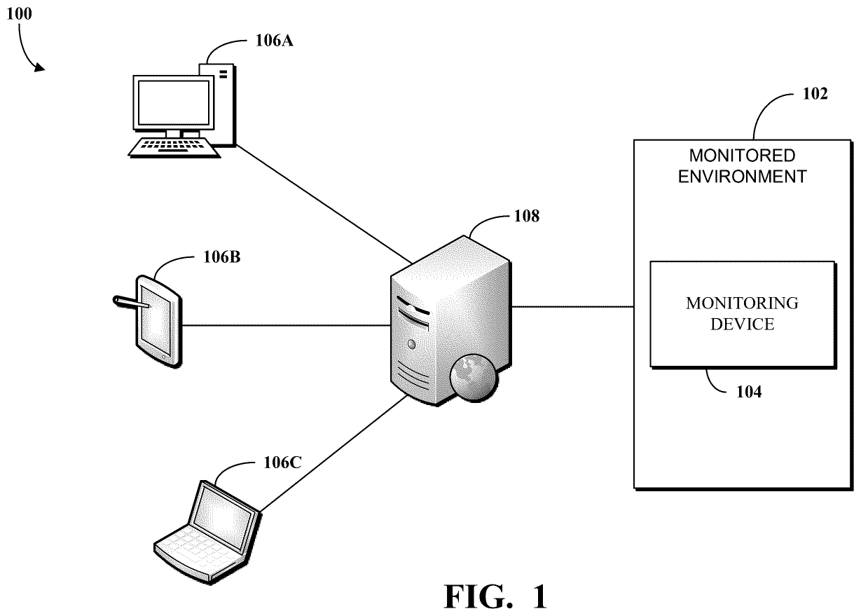

FIG. 1 is a schematic of an example of a system 100 according to implementations of this disclosure. The system 100 includes a monitored environment 102, a monitoring device 104, a user device 106, and a server 108.

The monitored environment 102 can be a patient hospital room, a nursing home room, a room of a home patient, a manufacturing line, a workstation, a laboratory, and the like. The monitored environment 102 includes and/or can be viewed using the monitoring device 104. The monitored environment 102 can be remotely monitored from the user device 106. The user device 106 can be one or more of a desktop computer 106A, a mobile device 106B (such as tablet, a smart phone, and the like), a laptop computer 106C, or some other device that can be used to access, communicate with, and/or control (directly or indirectly) the monitoring device 104. A user (not shown) of the user device 106 can monitor the monitored environment 102 via the monitoring device 104. That the monitored environment 102 is remotely monitored by the user means that the user may not physically be in the monitored environment 102 while performing the monitoring.

In the case that the monitored environment 102 is a patient hospital room, the user can be a physician, a nurse, another health-care practitioner, a family member of the patient, and/or the like. For example, the physician may be remotely responding to (e.g., diagnosing, mitigating, assessing, etc.) a patient emergency or remotely performing patient rounds. The nurse may be monitoring patients, including the monitored environment 102 from a nurses station to, for example, ensure that no patient is falling, is in need of help, is distressed, and/or the like. The family member of the patient may remotely visit with the patient using the monitoring device 104.

The monitoring device 104 can be configured to and/or used to capture video, images, audio, environmental conditions, or other characteristics of the monitored environment. The characteristics of the monitored environment can be transmitted to one or more users of the user devices 106. Via the user device 106, the user can interact with the monitoring device, such as by sending and/or receiving captured video and/or audio, sending commands to the monitoring device 104, and the like.

The user device 106 and the monitoring device 104 can communicate via the server 108. For example, the user device 106 can send commands to the server 108, which relays the command to the monitoring device. Similarly, the monitoring device 104 can send information to the server 108, which relays the information to the user device 106.

To illustrate, the monitoring device 104 can include a camera that is configured to view the monitored environment 102. The user device 106 can issue a request to the server 108 to establish a connection with the monitoring device 104. The server 108 can establish the connection. Issuing a request to the server 108 to establish a connection can include, for example, the user device 106 connecting to a patient by the patient's room number or name; the server 108 determining the monitoring device 104 of the patient (i.e., the monitoring device that is in the patient's room); and the server 108 connecting the user device 106 and the monitoring device 104. The connection session may be a video communication session during which the user can communicate visually and/or verbally with a person in the patient's room. The user device 106, may during the connection session, send a pan, tilt, or zoom (PTZ) command to the camera of the monitoring device 104 via the server 108. The monitoring device 104 can update the view of the monitored environment according to the PTZ command and send back, via the server 108, a video and/or image of the updated view of the monitored environment, which can then be displayed on a display of the user device 106. In an example, the server 108 can allow certain users to control monitoring device and not allowing other user devices to control the monitoring device.

In another example (not shown), the user device 106 can establish a peer-to-peer communication channel with the monitoring device 104. For example, in response to the connection request, the server 108 can facilitate the establishment of the peer-to-peer (e.g., direct) communication between the user device 106 and the monitoring device 104.

The server 108 can be deployed (e.g., physically located) on premise at the location of the monitored environment. The server 108 can be deployed on a same local area network (LAN) of the monitoring device 104. The server 108 can be deployed on a same wide area network (WAN) of the monitoring device 104. The server 108 can be a cloud-based server. Other deployments of the server 108 are possible.

The monitoring device 104, the user device 106, and the server 108 can communicate over any suitable network. The network (not shown) can be, for example, the Internet or an Internet Protocol (IP) network, such as the World Wide Web. The network can be a LAN, a WAN, a virtual private network (VPN), cellular telephone network, a private network, an extranet, an intranet, any other means of transferring information (e.g., video streams, audio streams, images, other information), or a combination thereof from one end point to another end point.

In an example, the user device 106 and the monitoring device 104 may communicate using a real-time transport protocol (RTP) for transmission of the media content, which may be encoded, over the network. In another implementation, a transport protocol other than RTP may be used (e.g., a Hypertext Transfer Protocol-based (HTTP-based) streaming protocol). For example, the user device 106 can transmit and/or receive media content (e.g., audio and/or video content) to and/or from the monitoring device 104 via Web Real-Time Communication (WebRTC), which provides web browsers and mobile applications with real-time communication. However, the disclosure herein is not so limited, and any other real-time transmission protocol can be used.

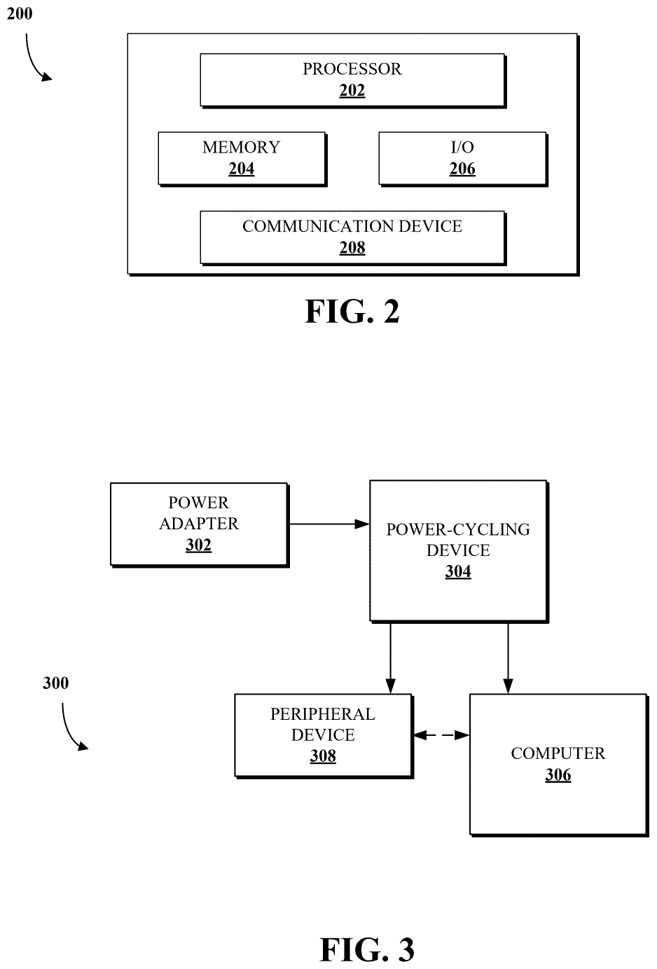

FIG. 2 is a block diagram of an example of a computing device 200. Each of the monitoring device 104, the user device 106, or the server 108 can be implemented, at least partially, by the computing device 200.

The computing device 200 can be implemented by any configuration of one or more computers, such as a microcomputer, a mainframe computer, a supercomputer, a general-purpose computer, a special-purpose/dedicated computer, an integrated computer, a database computer, a remote server computer, a personal computer, a laptop computer, a tablet computer, a cell phone, a personal data assistant (PDA), a wearable computing device, or a computing service provided by a computing service provider, for example, a web host or a cloud service provider. In some implementations, the computing device can be implemented in the form of multiple groups of computers that are at different geographic locations and can communicate with one another, such as by way of a network. While certain operations can be shared by multiple computers, in some implementations, different computers are assigned to different operations. In some implementations, the system 100 can be implemented using general-purpose computers/processors with a computer program that, when executed, carries out any of the respective methods, algorithms, and/or instructions described herein. In addition, or alternatively, for example, special-purpose computers/processors including specialized hardware can be utilized for carrying out any of the methods, algorithms, or instructions described herein.

The computing device 200 can have an internal configuration of hardware including a processor 202 and a memory 204. The processor 202 can be any type of device or devices capable of manipulating or processing information. In some implementations, the processor 202 can include a central processor (e.g., a central processing unit or CPU). In some implementations, the processor 202 can include a graphics processor (e.g., a graphics processing unit or GPU). Although the examples herein can be practiced with a single processor as shown, advantages in speed and efficiency can be achieved by using more than one processor. For example, the processor 202 can be distributed across multiple machines or devices (each machine or device having one or more processors) that can be coupled directly or connected via a network (e.g., a local area network). The memory 204 can include any transitory or non-transitory device or devices capable of storing executable codes and data that can be accessed by the processor (e.g., via a bus). The memory 204 herein can be a random-access memory (RAM) device, a read-only memory (ROM) device, an optical/magnetic disc, a hard drive, a solid-state drive, a flash drive, a security digital (SD) card, a memory stick, a compact flash (CF) card, or any combination of any suitable type of storage device. In some implementations, the memory 204 can be distributed across multiple machines or devices, such as in the case of a network-based memory or cloud-based memory. The memory 204 can include data (not shown), an operating system (not shown), and an application (not shown). The data can include any data for processing (e.g., an audio stream, a video stream, a multimedia stream, user commands, and/or other data). The application can include programs that permit the processor 202 to implement instructions to generate control signals for performing functions of the techniques in the following description.

In some implementations, in addition to the processor 202 and the memory 204, the computing device 200 can also include a secondary (e.g., external) storage device (not shown). When present, the secondary storage device can provide additional memory when high processing needs exist. The secondary storage device can be a storage device in the form of any suitable non-transitory computer-readable medium, such as a memory card, a hard disk drive, a solid-state drive, a flash drive, or an optical drive. Further, the secondary storage device can be a component of the computing device 200 or can be a shared device accessible via a network. In some implementations, the application in the memory 204 can be stored in whole or in part in the secondary storage device and loaded into the memory 204 as needed for processing.

In addition to the processor 202 and the memory 204, the computing device 200 can include input/output (I/O) devices. For example, the computing device 200 can include an I/O device 206. The I/O device 206 can be implemented in various ways, for example, it can be a display that can be coupled to the computing device 200 and configured to display a rendering of graphics data. The I/O device 206 can be any device capable of transmitting a visual, acoustic, or tactile signal to a user, such as a display, a touch-sensitive device (e.g., a touchscreen), a speaker, an earphone, a light-emitting diode (LED) indicator, or a vibration motor. The I/O device 206 can also be any type of input device either requiring or not requiring user intervention, such as a keyboard, a numerical keypad, a mouse, a trackball, a microphone, a touch-sensitive device (e.g., a touchscreen), a sensor, or a gesture-sensitive input device. If the I/O device 206 is a display, for example, it can be a liquid crystal display (LCD), a cathode-ray tube (CRT), or any other output device capable of providing a visual output to an individual. In some cases, an output device can also function as an input device. For example, the output device can be a touchscreen display configured to receive touch-based input.

The I/O device 206 can alternatively or additionally be formed of a communication device for transmitting signals and/or data. For example, the I/O device 206 can include a wired means for transmitting signals or data from the computing device 200 to another device. For another example, the I/O device 206 can include a wireless transmitter or receiver using a protocol compatible to transmit signals from the computing device 200 to another device or to receive signals from another device to the computing device 200.

In addition to the processor 202 and the memory 204, the computing device 200 can optionally include a communication device 208 to communicate with another device. Optionally, the communication can be via a network. The network can be one or more communications networks of any suitable type in any combination, including, but not limited to, networks using Bluetooth communications, infrared communications, near-field communications (NFCs), wireless networks, wired networks, local area networks (LANs), wide area networks (WANs), virtual private networks (VPNs), cellular data networks, or the Internet. The communication device 208 can be implemented in various ways, such as a transponder/transceiver device, a modem, a router, a gateway, a circuit, a chip, a wired network adapter, a wireless network adapter, a Bluetooth adapter, an infrared adapter, an NFC adapter, a cellular network chip, or any suitable type of device in any combination that is coupled to the computing device 200 to provide functions of communication with the network.

The computing device 200 can also include or be in communication with an image-sensing device (not shown), for example a camera, or any other image-sensing device now existing or hereafter developed that can sense an image such as the image of a user operating the computing device 200 or a view of a monitored environment. The image-sensing device can be positioned such that it is directed to capture a view of the monitored environment. For example, the image-sensing device can be directed toward a patient and/or a patient bed in a hospital room. In an example, the position and optical axis of the image-sensing device can be configured and/or controlled such that the field of vision (i.e., the view) includes an area of interest.

The computing device 200 can also include or be in communication with a sound-sensing device, for example a microphone, or any other sound-sensing device now existing or hereafter developed that can sense sounds near the computing device 200. The sound-sensing device can be positioned or controlled to be positioned such that it is directed toward a monitored environment so as to capture speech, other utterances, or other sounds within the monitored environment. The sound-sensing device can be configured to receive sounds, for example, speech or other utterances made by the user while the user operates the computing device 200. The computing device 200 can also include or be in communication with a sound playing device.

The computing device 200 (and any algorithms, methods, instructions, etc., stored thereon and/or executed thereby) can be realized in hardware including, for example, intellectual property (IP) cores, application-specific integrated circuits (ASICs), programmable logic arrays, optical processors, programmable logic controllers, microcode, firmware, microcontrollers, servers, microprocessors, digital signal processors, or any other suitable circuit. In this disclosure, the term “processor” should be understood as encompassing any of the foregoing, either singly or in combination. The terms “signal,” “data,” and “information” are used interchangeably.

FIG. 3 is a block diagram of an example of a system 300 for power cycling electronic devices according to implementations of this disclosure. The system 300 includes a power adapter 302, a power-cycling device 304, a computer 306, and a peripheral device 308. The peripheral device 308 may be an audio interface, a camera, a speakerphone, a microphone, a scanner, a printer, or the like.

The power adapter 302 can be any power supply capable of supplying power from a wall outlet to an electronic device such as the computer 306, the peripheral device 308, or the like. To be more specific, the power adapter 302 may be capable of converting power from the wall outlet to a form suitable for the electronic device. The computer 306 may be the computing device 200 of FIG. 2 or the monitoring device 104 of FIG. 1. In either case, the power adapter 302 supplies (i.e., delivers) power to the power-cycling device 304. The power-cycling device 304 may supply power to any electronic device such as the computer 306, the peripheral device 308, or the like.

The computer 306 may be connected to some other peripheral or external device, such as the peripheral device 308. The peripheral device 308 may be the sound sensing device as described above in relation to FIG. 2.

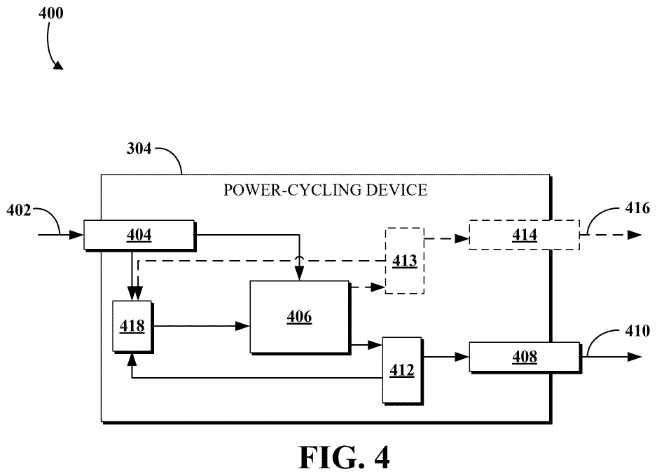

FIG. 4 is a block diagram 400 of the power-cycling device 304 of FIG. 3. The power-cycling device 304 may receive an input flow of electricity 402 from a power source (such as the power adapter 302 of FIG. 3). The input flow of electricity 402 is received at an input jack 404. The input flow of electricity 402 is routed via the input jack 404 to both an electronic switch 406 and a controller 418. The electronic switch 406 may be a power relay module, a switching transistor, or another suitable switching device. When closed, the electronic switch 406 enables the input flow of electricity 402 to flow (e.g., continue to flow) to a first output jack 408 through a sensor 412, which is a power consumption sensor. Via the first output jack 408, the input flow of electricity 402 is output as a first output flow of electricity 410. Additionally, when the electronic switch 406 is closed, the electronic switch 406 may optionally enable the input flow of electricity 402 to flow to a second output jack 414 through an additional, optional sensor 413, which is also a power consumption sensor. Via the second output jack 414, the input flow of electricity 402 is routed as a second output flow of electricity 416. In other words, the electronic switch 406 receives power from the input flow of electricity 402 and controls the delivery of power to a first output flow of electricity 410 and optionally a second output flow of electricity 416.

The controller 418 may be a microcontroller (such as an Arduino® Uno, an Arduino® micro, an Arduino® Nano, an ESP32, or the like). The controller 418 receives power from the input jack 404, ensuring it remains powered whenever the device is connected to a power source. The controller 418 may be configured to receive sensor data from the sensor 412 at a regular intervals (e.g., every 1 second, every 15 seconds, every 30 second, every 45 seconds, etc.). The sensor 412 is capable of measuring the power consumption between the electronic switch 406 and an electronic device connected to the second output flow of electricity 410. The sensor 412 may be or include a current sensor, a voltage sensor, a power meter integrated circuit or another sensor suitable for measuring power consumption. If the controller 418 determines that the power consumption, based on sensor data received from the sensor 412, is below a minimum threshold value, the controller 418 may send a signal to the electronic switch 406 instructing the electronic switch 406 to open. As a result, the input flow of electricity 402 is stopped from flowing to (e.g., reaching) the first output jack 408 and the second output jack 414, thereby ceasing (i.e., stopping) the flow of electricity to the connected electronic devices.

Additionally, the controller 418 may be configured to receive sensor data from the optional sensor 413 at regular intervals (e.g., every 1 second, every 15 seconds, every 30 second, every 45 seconds, etc.). The optional sensor 413 is capable of measuring the power consumption between the electronic switch 406 and an electronic device connected to the second output flow of electricity 416. The optional sensor 413 may be the same or similar to the sensor 412. If the controller 418 determines that the power consumption, based on sensor data received from the optional sensor 413, is below a minimum threshold value, the controller 418 may send (i.e., relay) a signal to the electronic switch 406 instructing the electronic switch to open. As a result, the input flow of electricity 402 is stopped from flowing to (e.g., reaching) the first output jack 408 and the second output jack 414, thereby ceasing the flow of electricity to the connected electronic devices.

For example, consider a hospital setting where the room of a patient is equipped with a monitoring device (such as the monitoring device 104 of FIG. 1) connected to a power-cycling device (such as the power-cycling device 304 of FIG. 3). A physician located remotely accesses the live feed from the monitoring device. During the physician's virtual rounds, the physician notices that the video feed from the patient's room has frozen. To resolve the issue, a shutdown command can be sent to the monitoring device. While a shutdown command initiates a controlled software shutdown of the monitoring device, it does not provide a mechanism for automatically restarting (i.e., turning back on) the monitoring device. Once the monitoring device shuts down (i.e., turns off), the power consumption being measured by the power consumption sensor (such as the sensor 412 of FIG. 4) drops below the minimum threshold value (e.g., may drop to zero). The power-cycling device, via the controller 418, can detect the cessation of the power consumption causing the power-cycling device to stop the flow of electricity (i.e., cease the flow of electricity) to the monitoring device and any other optionally connected peripheral devices (e.g., a camera).

After waiting a delay period, the power-cycling device can restart the flow of electricity to the monitoring device and any other optionally connected peripheral devices. Once the flow of electricity is restored, the monitoring device, having been configured to wake on power or equivalent functionality, restarts and resumes transmitting the live feed. The wake on power functionality can be implemented through various means, such as a basic input/output system (BIOS) setting on a computer or a similar configuration on other electronic devices. The electronic device, upon sensing the return of power, initiates the boot-up sequence and starts up (i.e., turns on).

This automated power cycling, initiated remotely, eliminates the need for a nurse or technician to physically visit the patient's room, saving valuable time and resources. Moreover, it ensures continuous monitoring of the patient's condition, even in the face of technical glitches, improving the overall quality of care.

In another example, consider a home security system including a central control unit (connected to the first output flow of electricity 410) and a wireless surveillance camera (connected to the second output flow of electricity 416). In the event of a network outage or software glitch, the wireless surveillance camera may become unresponsive, ceasing to transmit video feeds to the central control unit. The power-cycling device, with its integrated current sensors (e.g., sensor 412 and optional sensor 413), may detect this inactivity as a drop in power consumption below the minimum threshold value. In response, the controller 418 can signal the electronic switch 406 to open, cutting off power to both the central control unit and the wireless surveillance camera. After a delay period, the electronic switch 406 closes again, restarting both devices and restoring normal operation without requiring any on-site intervention. This automated power cycling capability enhances the reliability and resilience of the home security system, particularly in scenarios where physical access to the devices may be challenging or impractical.

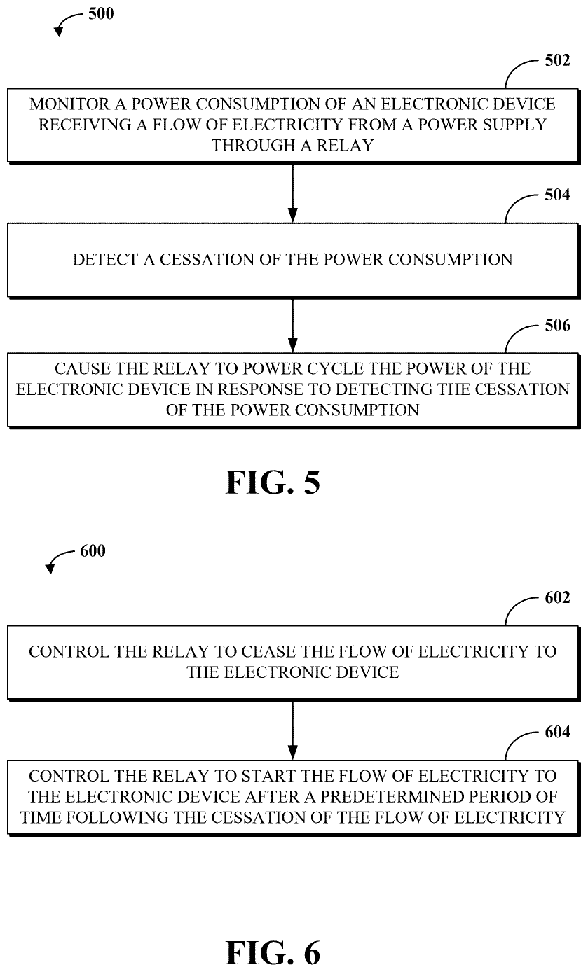

FIG. 5 is an example of a flowchart of a technique 500 for power cycling an electronic device using a power-cycling device. The technique 500 can be stored in a memory, such as the memory 204 of FIG. 2, as instructions that can be executed by a processor (such as the controller 418 of FIG. 4) of a micro-controller (such as an Arduino® Uno, an Arduino® micro, an Arduino® Nano, an ESP32, or the like). In some implementations, some or all operations of the technique 500 may be performed on a microcontroller, such as by the controller 418 of FIG. 4.

At 502, the power consumption of the electronic device is monitored. The electronic device receives a flow of electricity from a power supply through a relay (such as the electronic switch 406 of FIG. 4). The power consumption is monitored using a relay controller (such as the controller 418 of FIG. 4) connected to a power consumption sensor (such as the sensor 412 of FIG. 4). In other words, the relay controller receives sensor data from the power consumption sensor, allowing the relay controller to keep track of the power consumption of the electronic device and identifies any changes or anomalies that might indicate a need for intervention.

For example, the electronic device may be the monitoring device 104 of FIG. 1. The monitoring device 104 may be connected to the power-cycling device 304, as such, the flow of electricity flows from a power source, such as the power adapter 302, through the power-cycling device 304 to the monitoring device 104. As the flow of electricity flows through the power-cycling device 304, the sensor 412 measures the power consumption of the monitoring device 104. The sensor 412 sends the power consumption data to the controller 418. The controller 418 monitors the power consumption levels based on the power consumption data received from the sensor 412.

At 504, a cessation of the power consumption is detected. The cessation of the power consumption is detected by the relay controller based on the power consumption data received from the power consumption sensor. In other words, the relay controller analyzes the stream of power consumption data received from the power consumption sensor monitoring for a specific pattern within the power consumption data that signifies a cessation of the power consumption. This pattern may be a sudden and significant drop in the measured power level, falling below a minimum threshold value. Such a drop in the power consumption may indicate that the electronic device has shut down, has become unresponsive, or is experiencing a malfunction that has disrupted the normal power usage of the electronic device.

For example, the power-cycling device 304 monitors the power consumption of the monitoring device 104 as described above. Due to a sudden power surge the monitoring device 104 is caused to unexpectedly shut down. The controller 418 of the power-cycling device 304, can detect a decline in the power consumption of the monitoring device 104 via the power consumption data received from the sensor 412.

At 506, in response to detecting the cessation of the power consumption, the relay controller causes the relay to power cycle the power to the electronic device. That is, upon the detection of the power consumption drop by the electronic device, the relay controller initiates a corrective action. The relay controller sends a command to the relay, instructing it to perform a power cycle on the electronic device. This power cycle involves a controlled interruption and subsequent restoration of the flow of electricity from the power supply to the electronic device. In other words, the relay, upon receiving the command from the relay controller, will temporarily open the circuit of the relay stopping the flow of electricity to the electronic device. After a delay period, designed to allow for a complete discharge of any residual electricity within the circuitry of the electronic device, the relay controller will close the circuit of the relay, re-establishing the flow of electricity to the electronic device. The delay period may be measured in milli-seconds, seconds, minutes, or the like. In an example, the delay period may be set to 30 seconds; however, other delay periods may be used as appropriate for the electronic device connected to the power-cycling device 304. This sequence of power interruption and restoration is intended to mimic the effect of physically unplugging and then re-plugging the electronic device.

For example, the controller 418 may detect that the power consumption of the monitoring device 104 has ceased. The cessation of the power consumption may be attributed to a variety of factors, including but not limited to, an unexpected power outage or surge, a hardware malfunction, a software crash or freeze, tampering, or the like. The controller 418 may detect the cessation of the power consumption based on measurements received from the sensor 412. When the controller 418 detects the cessation of the power consumption, the controller 418 causes the electronic switch 406 to open ceasing the flow of electricity through to the first output jack 408 and subsequently to the monitoring device 104. After a delay period, the controller 418 causes the electronic switch 406 to close. Once the electronic switch 406 is closed, the flow of electricity to the monitoring device 104 resumes and the monitoring device 104 can resume operation.

FIG. 6 is an example of a flowchart of a technique 600 for power cycling an electronic device. The technique 600 can be stored in a memory, such as the memory 204 of FIG. 2, as instructions that can be executed by a processor (such as the controller 418 of FIG. 4) of a micro-controller (such as an Arduino® Uno, an Arduino® micro, an Arduino® Nano, an ESP32, or the like). In some implementations, some or all operations of the technique 600 may be performed on a microcontroller, such as by the controller 418 of FIG. 4.

At 602, the relay is controlled to cease the flow of electricity to the electronic device. That is, the relay controller, such as the controller 418 of FIG. 4, sends a signal to the relay (i.e., the electronic switch 406) to stop the flow of electricity to the electronic device (i.e., the monitoring device 104 of FIG. 1). The cessation of the flow of electricity is a direct response to the detection of the cassation of the power consumption as described above in reference to FIG. 5. The relay responds to a control signal from the relay controller, interrupting the electrical circuit and stopping the flow of electricity to the electronic device. This power interruption serves as the initial phase of the power cycling process, designed to reset the electronic device.

At 604, the relay is controlled to start the flow of electricity after a delay period following the cessation of the flow of electricity. That is, after the delay period (i.e., interval) elapses following the cessation of the flow of electricity, the controller signals the relay to close, thereby restarting the flow of electricity. This interval serves an important purpose in the power cycling process as it allows any residual electrical charge within the circuits of the electronic device to dissipate completely. Allowing the interval between the cessation of the flow of electricity and the restarting of the flow of electricity ensures a clean and effective power cycle of the electronic device. The duration of this predetermined period can be selected to be long enough for a full discharge but short enough to minimize downtime. The predetermined period can be 30 seconds. However, other durations may be appropriate depending on the type of electronic device. The power-cycling device can be configured with the predetermined period. Once the delay period has elapsed, the relay controller issues a command to the relay, instructing it to close the circuit and resume the flow of electricity to the electronic device. This restoration of power allows the device to boot up afresh, potentially resolving any underlying issues that caused the initial cessation of the power consumption.

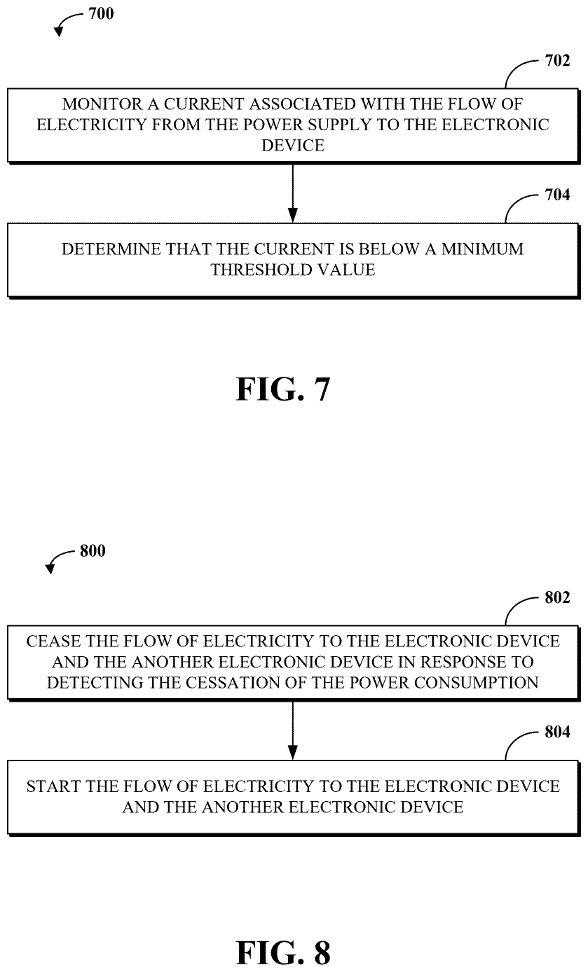

FIG. 7 is an example of a flowchart of a technique 700 for determining the cessation of a power consumption of an electronic device. The technique 700 can be implemented by a power-cycling device, such as the power-cycling device 304 of FIG. 3 and FIG. 4. The technique 700 can be stored in a memory, such as the memory 204 of FIG. 2, as instructions that can be executed by a processor (such as the controller 418 of FIG. 4) of a micro-controller (such as an Arduino® Uno, an Arduino® micro, an Arduino® Nano, an ESP32, or the like). In some implementations, some or all operations of the technique 700 may be performed on a microcontroller, such as by the controller 418 of FIG. 4.

At 702, a current (i.e., an electrical current) associated with the flow of electricity from the power supply to the electronic device (e.g., the monitoring device 104 of FIG. 1) is monitored. This involves real-time measurement and tracking of the magnitude of the current, which can fluctuate depending on the operational state and power demands of the electronic device. By monitoring the current through a current sensor, such as the sensor 412 of FIG. 4, the power-cycling device can be configured to determine the power consumption patterns of the electronic device.

At 704, a determination is made that the current is below a minimum threshold value. In other words, a decision point is reached within the power cycling process. The current being monitored, which represents the power consumption of the electronic device, is compared against the minimum threshold value. The minimum threshold value serves as a benchmark for normal operation, delineating the expected range of current flow during typical device activity. If the measured current falls below this minimum threshold value, a potential issue is indicated. This could indicate, but is not limited to, that the device has entered a low-power state, become unresponsive, is experiencing a malfunction that has disrupted its power consumption patterns, or shutdown (e.g., powered off). The determination that the current is below the minimum threshold value acts as a catalyst for the subsequent steps in the power cycling process, prompting the relay controller (i.e., the controller 418 of FIG. 4) to initiate corrective measures to address the detected anomaly.

FIG. 8 is an example of a flowchart of a technique 800 for power cycling multiple electronic devices. The technique 800 can be stored in a memory, such as the memory 204 of FIG. 2, as instructions that can be executed by a processor (such as the controller 418 of FIG. 4) of a micro-controller (such as an Arduino® Uno, an Arduino® micro, an Arduino® Nano, an ESP32, or the like). In some implementations, some or all operations of the technique 800 may be performed on a microcontroller, such as by the controller 418 of FIG. 4. The technique 800 can be used to power-cycle at least a secondary device in response to detecting the cessation of power consumption by a primary device. The primary device can be the computer 306 of FIG. 3 and the secondary device can be the peripheral device 308 of FIG. 3. That is, the primary device may be the monitoring device 104 of FIG. 1 and the secondary device may be the peripheral device 308 of FIG. 3.

At 802, the flow of electricity to the electronic device (i.e., primary device) and another electronic device (i.e., secondary device) is ceased in response to detecting the cessation of the power consumption by the primary device. The flow of electricity is ceased (i.e., halted), not only to the primary device but also to the secondary device that is also connected to the power-cycling device. The flow of electricity may be ceased, using a technique similar to (e.g., the same as) the technique 600 described with respect to FIG. 6, by using a relay (e.g., electronic switch 406) controlled by a relay controller (e.g., controller 418).

The simultaneous interruption of the flow of electricity to both the primary and the secondary devices serves a dual purpose. First, it ensures a complete discharge of the primary device, clearing any lingering faults or errors that may have caused the power consumption anomaly. Secondly, it addresses the potential interdependence between the two devices. In other words, the two devices may not be entirely independent of each other, as such, the two devices may have a functional or communicative connection that necessitates coordinated operation between the two devices.

To illustrate, in the context of a home security system, a wireless surveillance camera (i.e., the secondary device) might be dependent on a central control unit (i.e., the primary device) to process and store the video footage. If the central control unit encounters a problem, the camera might continue to operate but its data would not be properly recorded or accessed. Power cycling both the wireless surveillance camera and the central control unit forces both device to re-sync and ensure that the home security system functions as intended.

By stopping the flow of electricity to both the primary device and the secondary device, the power-cycling device eliminates any possibility of the secondary device inadvertently contributing to the malfunction of the primary device or hindering the recovery process. This coordinated power cycle sets the stage for a comprehensive system reset, maximizing the chances of restoring normal operation for both the primary device and the secondary device.

At 804, the flow of electricity to the electronic device (i.e., primary device) and the another electronic device (i.e., secondary device) is restarted. That is, after a delay period has lapsed following the cessation of the flow of electricity, the power-cycling device initiates the restoration of the flow of electricity to both the primary device and the secondary device. The restarting of the flow of electricity may be accomplished, using a technique similar to (e.g., the same as) the technique 600, by using a relay controlled by a relay controller.

The coordinated reactivation of the flow of electricity is designed to power-cycle both the primary device and the secondary device and clear any underlying issues. The relay, which previously acted as a barrier to the flow of electricity, is now controller, using the relay controller, to close the circuit, allowing the flow of electricity to return to both devices. The renewed flow of electricity enables the devices to boot up afresh, resuming their normal operation.

In some embodiments, the secondary device may be the device that is malfunctioning and shutting down the primary device, causing the power consumption to drop below the minimum threshold value, will trigger a power cycle of both devices. For example, consider a monitoring device 104 connected to a peripheral device 308 wherein the monitoring device 104 and the peripheral device 308 are both powered by a power-cycling device 304 and the peripheral device 308 is a camera. A physician may be able to access the monitoring device 104; however, the physician is unable to view the live feed of the camera. As such, the peripheral device 308 may be malfunctioning and require a power cycle. The monitoring device 104 may be remotely shut down. Once the monitoring device 104 has shutdown the power consumption of the monitoring device 104 drops below the minimum threshold value. This will cause the power-cycling device to perform a power cycle for both the monitoring device 104 and the peripheral device 308.

In some embodiments the power consumption of the secondary device may be monitoring instead of or in addition to the power consumption of the primary device. For example, the primary device may be the computer 306 and the secondary device may be a printer. The computer 306 may be connected to the first output jack 408 of the power-cycling device 304 and the printer may be connected to the second output jack 414. Additionally, the computer 306 and the printer may be communicatively connected. That is the computer 306 and the printer may be connected via a wired connection (e.g., universal serial bus (USB) connection, ethernet connection, parallel connection, serial connection, etc.) or via a wireless connection (e.g., Wi-Fi connection, Bluetooth connection, Cloud connection, near-field communication (NFC) connection, etc.).

In this example, the problem may be with the connection between the computer 306 and the printer. Additionally, it may be easier to turn off the printer which is connected to the second output jack 414 of the power-cycling device 304. The controller 418 of the power-cycling device 304 may detect the drop in power consumption via the measurements received from the sensor 413 measuring the power consumption between the electronic switch 406 and the second output jack 414. The controller 418 as detecting that the power consumption of the printer is below the minimum threshold value may send a signal to the electronic switch 406 causing the flow of electricity to cease to flow to both the first output jack 408 and the second output jack 414.

After a delay period after ceasing the flow of electricity from the electronic switch 406, the controller 418 may send a signal to the electronic switch 406 signaling the electronic switch 406 to close the circuit and resume the flow of electricity to the first output jack 408 and the second output jack 414.

For simplicity of explanation, the techniques 500, 600, 700 and 800 of FIGS. 5, 6, 7, and 8 respectively, are each depicted and described as a respective series of blocks, steps, or operations. However, the blocks, steps, or operations in accordance with this disclosure can occur in various orders and/or concurrently. Additionally, other steps or operations not presented and described herein may be used. Furthermore, not all illustrated steps or operations may be required to implement a technique in accordance with the disclosed subject matter.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

One general aspect includes a system. The system includes a relay configurable to control a flow of electricity from a first power supply. The system also includes a relay controller powered by a second power supply and configured to control operations of the relay. The system also includes an electronic device configured to transmit heartbeat signals, where the heartbeat signals are received by the relay controller, and where the relay controller is configured to: terminate the flow of electricity in response to determining a cessation of the heartbeat signals, and restart the flow of electricity after terminating the flow of electricity.

Implementations may include one or more of the following features. The system where determining the cessation of the heartbeat signals may include receiving a first heartbeat signal, and determining that a second heartbeat signal is not received within a predetermined amount of the first heartbeat signal. The flow of electricity can extend from a source to the electronic device via the relay. The relay controller can be configured to receive the heartbeat signals from the electronic device using a universal serial bus connection between the relay controller and the electronic device. The second power supply can extend from the electronic device to the relay controller. The relay controller can be exclusively powered by the electronic device. Implementations of the described techniques may include hardware, a method or process, or computer software on a computer-accessible medium.

One general aspect includes a method. The method includes detecting, by a power-cycling device, a cessation of receipt of a heartbeat signals from an electronic device. The method also includes, in response to detecting, by the power-cycling device, the cessation of the heartbeat signals: stopping, by the power-cycling device, a flow of electricity from a power source to the electronic device; and restarting, by the power-cycling device, the flow of electricity to the electronic device after stopping the flow of electricity to the electronic device. Other embodiments of this aspect include corresponding computer systems, apparatus, and computer programs recorded on one or more computer storage devices, each configured to perform at least some of the actions of the methods.

Implementations may include one or more of the following features. The method where stopping the flow of electricity to the electronic device may include configuring a relay of the power-cycling device to stop the flow of electricity to the electronic device, where the relay receives the electricity from a power supply for delivery to the electronic device. The relay can be controlled by a relay controller. The power-cycling device can be powered by another power source that is different from the power source. The another power source is the electronic device. The heartbeat signals are received via a universal serial bus connection. The method the method may include receiving, by the power-cycling device, a command signal from a remote device; and in response to receiving the command signal, stopping, by the power-cycling device, the flow of electricity to the electronic device. Implementations of the described techniques may include hardware, a method or process, or computer software on a computer-accessible medium.

One general aspect includes an apparatus. The apparatus includes a relay; and a relay controller may include processing circuitry configured to execute instructions to detect a cessation of receipt of heartbeat signals from an electronic device; stop, in response to detecting the cessation of the heartbeat signals, a flow of electricity to the electronic device; and restart the flow of electricity to the electronic device. Other embodiments of this aspect include corresponding computer systems, apparatus, and computer programs recorded on one or more computer storage devices, each configured to perform the actions of the methods.

Implementations may include one or more of the following features. The apparatus where the electronic device can be a computer. The heartbeat signals can be received from software executed by the computer. The flow of electricity to the electronic device can be stopped using the relay. The relay can be controlled by the relay controller. The relay controller can receive the heartbeat signals using a universal serial bus connection between the electronic device and the relay controller. The processing circuitry can be configured to execute instructions to receive a command signal from a remote device; stop, in response to receiving the command signal, the flow of electricity to the electronic device; and restart the flow of electricity to the electronic device.

The word “example” is used herein to mean serving as an example, instance, or illustration. Any aspect or design described herein as “example” is not necessarily to be construed as being preferred or advantageous over other aspects or designs. Rather, use of the word “example” is intended to present concepts in a concrete fashion. As used in this application, the term “or” is intended to mean an inclusive “or” rather than an exclusive “or.” That is, unless specified otherwise or clearly indicated otherwise by the context, the statement “X includes A or B” is intended to mean any of the natural inclusive permutations thereof. That is, if X includes A; X includes B; or X includes both A and B, then “X includes A or B” is satisfied under any of the foregoing instances. In addition, the articles “a” and “an” as used in this application and the appended claims should generally be construed to mean “one or more,” unless specified otherwise or clearly indicated by the context to be directed to a singular form. Moreover, use of the term “an implementation” or the term “one implementation” throughout this disclosure is not intended to mean the same implementation unless described as such.

Implementations of the power-cycling device 304, and/or any of the components therein described with respect to FIG. 3 (and the techniques, algorithms, methods, instructions, etc., stored thereon and/or executed thereby) can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

Further, all or a portion of implementations of this disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or semiconductor device. Other suitable mediums are also available.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An apparatus, comprising:
a relay configured to control a flow of electricity from a power supply to an electronic device;
a relay controller configured to control an operation of the relay;
a sensor communicatively connected to the relay controller and configured to measure a power consumption of the electronic device wherein the relay controller is configured to:
detect, based on signals from the sensor, a cessation of the power consumption of the electronic device; and
cause the relay to power cycle the electronic device in response to detecting the cessation of the power consumption.

2. The apparatus of claim 1, wherein to cause the relay to power cycle the electronic device comprises to:
control the relay to cease the flow of electricity to the electronic device; and
control the relay to start the flow of electricity to the electronic device after a delay period following the cessation of the flow of electricity.

3. The apparatus of claim 1, wherein to detect the cessation of the power consumption comprises to:
measure, using the sensor, a current associated with the flow of electricity from the relay to the electronic device, and
determine that the current is below a minimum threshold value.

4. The apparatus of claim 1, wherein the electronic device is a computing device.

5. The apparatus of claim 2, wherein the relay is further configured to control the flow of electricity from the power supply to another electronic device.

6. The apparatus of claim 5, wherein to cause the relay to power cycle the electronic device comprises to:
control the relay to cease the flow of electricity to the electronic device and the another electronic device; and
control the relay to start, after the delay period following the cessation of the flow of electricity, the flow of electricity to the electronic device and the another electronic device.

7. The apparatus of claim 5, wherein:
the another electronic device is communicatively connected to the electronic device.

8. The apparatus of claim 7, wherein the another electronic device is a camera.

9. A method, comprising;
monitoring, based on sensor data from a sensor, a power consumption of an electronic device receiving a flow of electricity from a power supply through a relay;
detecting, based on the sensor data, a cessation of the power consumption; and
causing, by a relay controller, the relay to power cycle the power of the electronic device in response to detecting the cessation of the power consumption.

10. The method of claim 9, wherein the relay is controlled by the relay controller and the sensor is communicatively connected to the relay controller.

11. The method of claim 10, wherein causing the relay to power cycle the electronic device comprises:
controlling the relay to cease the flow of electricity to the electronic device; and
controlling the relay to start the flow of electricity to the electronic device after a delay period following the cessation of the flow of electricity.

12. The method of claim 10, wherein the detecting the cessation of the power consumption comprises:
monitoring, by the relay controller via the sensor, a current associated with the flow of electricity from the power supply to the electronic device; and
determining, by the relay controller, that the current is below a minimum threshold value.

13. The method of claim 10, wherein the relay is further configured to control the flow of electricity from the power supply to another electronic device.

14. The method of claim 13, wherein the causing the relay to power cycle the power of the electronic device comprises:
ceasing the flow of electricity to the electronic device and the another electronic device in response to detecting the cessation of the power consumption; and
starting, after a delay period following the cessation of the flow of electricity, the flow of electricity to the electronic device and the another electronic device.

15. The method of claim 13, wherein the another electronic device is communicatively connected to the electronic device.

16. A non-transitory computer-readable medium storing instructions operable to cause one or more processors to perform operations comprising:
receiving, from a sensor, a power consumption data of an electronic device receiving a flow of electricity from a power supply through a relay;
determining a cessation of power consumption by the electronic device based on a determination that the power consumption data being less than a minimum threshold value; and
power cycling the electronic device in response to determining the cessation of the power consumption.

17. The non-transitory computer-readable medium of claim 16, wherein the relay is controlled by a relay controller and the sensor is communicatively connected to the relay controller.

18. The non-transitory computer-readable medium of claim 17, wherein power cycling the electronic device comprises:
sending a signal to the relay to cease the flow of electricity to the electronic device for a delay period; and
sending a signal to the relay to restart the flow of electricity to the electronic device after the delay period lapses.

19. The non-transitory computer-readable medium of claim 17, wherein power cycling the electronic device comprises:
sending a signal to the relay to cease the flow of electricity to the electronic device and another electronic device for a delay period; and
sending a signal to the relay to restart the flow of electricity to the electronic device and the another electronic device after the delay period lapses.

20. The non-transitory computer-readable medium of claim 19, wherein the another electronic device is communicatively connected to the electronic device.
